(19) United States
(12) Patent Application Publication
(10) Pub. No.: US 2019/0341577 A1
(43) Pub. Date: Nov. 7, 2019

(54) DISPLAY DEVICE AND METHOD FOR MANUFACTURING SAME

(71) Applicant: Japan Display Inc., Minato-ku (JP)

(72) Inventors: Kazuto TSURUOKA, Minato-ku (JP); Kenji TORIBATAKE, Minato-ku (JP)

(73) Assignee: Japan Display Inc., Minato-ku (JP)

(21) Appl. No.: 16/511,031

(22) Filed: Jul. 15, 2019

Related U.S. Application Data
(63) Continuation of application No. PCT/JP2017/037524, filed on Oct. 17, 2017.

(30) Foreign Application Priority Data
Jan. 18, 2017 (JP) 2017-006664

(51) Int. Cl. H01L 51/52; H01L 51/56; H01L 27/32; H05K 1/18

(52) U.S. Cl. CPC H01L 51/5246; H01L 51/56; H05K 2201/10128; H05K 1/189; H01L 2251/5338; H01L 27/3244

(57) ABSTRACT

A display device includes a resin substrate; a display circuit layer on the resin substrate, the display circuit layer having a first area including a display area, the display circuit layer having a second area apart from the first area in a first direction; a first film attached to the first area of the display circuit layer via a first adhesive layer; a second film attached to the second area of the display circuit layer via a second adhesive layer; and a resin layer between the first area and the second area of the display circuit layer. The resin layer is in contact with an edge surface of the first film opposed to the second film. The resin layer is in contact with an edge surface of the second film opposed to the first film.

### CROSS-REFERENCE TO RELATED APPLICATION

This application is a continuation application of International Application PCT/JP2017/037524 filed on Oct. 17, 2017, which claims priority from Japanese patent application JP2017-006664 filed on Jan. 18, 2017. The contents of these applications are incorporated herein by reference in their entirety.

### BACKGROUND

### 1. Field

This relates to display devices and manufacturing methods therefor.

### 2. Description of the Related Art

Recently, bendable sheet displays using a luminous body such as an organic light emitting diode (OLED) have been developed (US2016/0174304A1 and US2014/0367644A1). The displays have a film attached thereto for reinforcement.

Attaching the film easily makes the display flat, while stress in the film makes an impact on the display when the display is made bent, making it preferable to have the film provided except on a curvature portion of the display with another member at the curvature portion. Liquid resin, for example, can be selected from a wider range of materials for providing at the curvature portion and its thickness is highly adjustable. However, a resin layer made from the liquid resin cured has no adhesiveness, resulting in a problem of lacking capability of re-attachment after exfoliation. Additionally, during manufacturing processes, thickness control of the resin layer is difficult due to flow of the liquid resin.

### SUMMARY

This is to aim at minimizing exfoliation of a resin layer without adhesiveness and aim at controlling thickness of the resin layer during manufacturing processes.

A display device includes a resin substrate; a display circuit layer on the resin substrate, the display circuit layer having a first area including a display area, the display circuit layer having a second area apart from the first area in a first direction; a first film attached to the first area of the display circuit layer via a first adhesive layer; a second film attached to the second area of the display circuit layer via a second adhesive layer; and a resin layer between the first area and the second area of the display circuit layer. The resin layer is in contact with an edge surface of the first film opposed to the second film. The resin layer is in contact with an edge surface of the second film opposed to the first film.

The resin layer is in contact with the second film on a side apart from the display area, minimizing exfoliation. The second film is attached, by means of a second adhesive layer, enabling re-attachment in spite of the exfoliation.

A method for manufacturing a display device, includes forming a display circuit layer on a resin substrate, the display circuit layer having a first area including a display area, the display circuit layer having a second area apart from the first area in a first direction; attaching a film to the display circuit layer between the first area and the second area, by means of an adhesive layer, the film having an opening; providing liquid resin on the display circuit layer and in the opening of the film; forming a resin layer by curing the liquid resin; and obtaining a product by cutting the film, the display circuit layer, and the resin substrate, the product including at least a part of the resin layer, the product including a part of the film in close contact with the resin layer and in each of the first area and the second area.

The liquid resin is provided to be dammed up by the opening of the film, whereby a thickness of the resin layer is controllable. The display device manufactured thereby has the resin layer in close contact with the film, on a side apart from the display area, minimizing exfoliation. The film is attached, by means of the adhesive layer, enabling re-attachment in spite of the exfoliation.

### BRIEF DESCRIPTION OF THE DRAWINGS

FIG. 1 is a plan view of a display device in a first embodiment.

FIG. 2 is a II-II line partially enlarged cross-sectional view of the display device in FIG. 1.

FIG. 3 is a diagram of how to use the display device in FIG. 1.

FIG. 4 is a IV-IV line cross-sectional view of the display device in FIG. 3.

FIG. 5 is an enlarged cross-sectional view of a curvature portion of the display device.

FIG. 6 is a diagram of an intermediate product during manufacture.

FIG. 7 is a diagram of a process of attaching a film to a display circuit layer, by means of an adhesive layer.

FIG. 8 is a diagram of a process of providing liquid resin in an opening of the film.

FIG. 9 is a diagram of a process of obtaining a product.

FIG. 10 is a plan view of a display device in a second embodiment.

FIG. 11 is a plan view of a display device in a third embodiment.

FIG. 12 is a XII-XII line cross-sectional view of the display device in FIG. 11.

FIG. 13 is a diagram of manufacturing method for the display device in the third embodiment.

### DETAILED DESCRIPTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

### First Embodiment

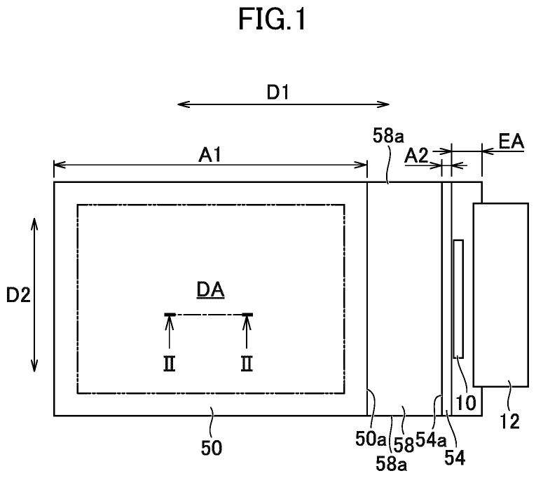

FIG. 1 is a plan view of a display device in a first embodiment. An organic electroluminescence display device exemplifies the display device. The display device is configured to display a full-color image made of a plurality of pixels (subpixels) in colors such as red, green, and blue. The display device has a display area DA where the plurality of pixels are arranged in a matrix shape. The display device has an integrated circuit chip 10 mounted thereon for driving elements to display images and has a flexible printed circuit board 12 connected thereto for externally electrical connection.

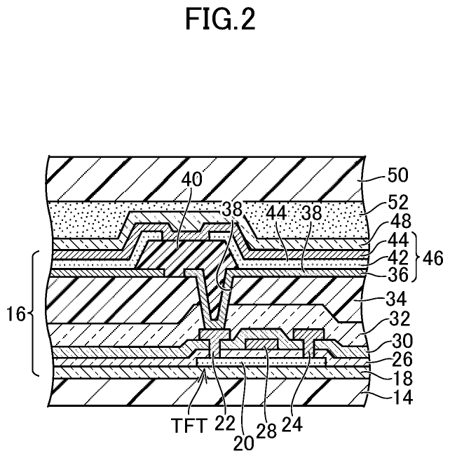

FIG. 2 is a II-II line partially enlarged cross-sectional view of the display device in FIG. 1. The display device has a resin substrate 14. The resin substrate 14 has a rectangular contour (e.g. elongated rectangle). The resin substrate 14 may be made from polyimide resin or polyethylene terephthalate, having flexibility.

A display circuit layer 16 with some layers is on the resin substrate 14. The display circuit layer 16 has a first area A1 in FIG. 1. The first area A1 includes the display area DA. The display circuit layer 16 has a second area A2 apart from the first area A1 in a first direction D1. The display circuit layer 16 has an externally electrical connection area EA (third area). The electrical connection area EA is farther from the first area A1 in the first direction D1 than the second area A2. The integrated circuit chip 10 is mounted on the electrical connection area EA and the flexible printed circuit board 12 is connected to the electrical connection area EA. One or both of the integrated circuit chip 10 and the flexible printed circuit board 12 may be in the electrical connection area EA.

The display circuit layer 16 includes an undercoat layer 18 for a barrier against impurities in the resin substrate 14. The undercoat layer 18 may be made of a silicon oxide film or a silicon nitride film, or have a laminated structure thereof. A semiconductor layer 20 is on the undercoat layer 18. A source electrode 22 and a drain electrode 24 are electrically connected to the semiconductor layer 20; a gate insulating film 26 covers the semiconductor layer 20. A gate electrode 28 is on the gate insulating film 26; an interlayer dielectric 30 covers the gate electrode 28. The source electrode 22 and the drain electrode 24 are configured to penetrate the gate insulating film 26 and the interlayer dielectric 30. The semiconductor layer 20, the source electrode 22, the drain electrode 24, and the gate electrode 28 constitute at least a part of a thin film transistor TFT. A passivation film 32 covers the thin film transistor TFT.

A planarization film 34 is on the passivation film 32. A plurality of pixel electrodes 36 (e.g. anodes) are on the planarization film 34 in response to the respective plurality of pixels (subpixels). The planarization film 34 is formed to be flat on a surface where at least the pixel electrodes 36 are provided. An organic material such as photosensitive acrylic resin tends to be used for the planarization film 34. The pixel electrode 36 is electrically connected to one of the source electrode 22 and the drain electrode 24 on the semiconductor layer 20, through a contact hole 38 bored through the planarization film 34 and the passivation film 32.

An insulation layer 40 is on the planarization film 34 and the pixel electrodes 36. The insulation layer 40 is on a peripheral portion of the pixel electrode 36, to expose a part (e.g. central portion) of the pixel electrode 36. The insulation layer 40 constitutes a bank around the part of the pixel electrode 36.

A light-emitting layer 42 is on the pixel electrode 36. The light-emitting layer 42 is individually (separately) on each pixel electrode 36, to emit light in blue, red, or green, in response to each pixel. The colors corresponding to respective pixels are not limited thereto and may include yellow or white. The light-emitting layer 42 may be formed by vapor deposition. Or, the light-emitting layer 42 may be formed all over the display area DA in FIG. 1, to extend to the plurality of pixels, whereby the light-emitting layer 42 may be continuous on the insulation layer 40. In such a case, the light-emitting layer 42 is formed by application of solvent dispersion. The light-emitting layer 42, extending to the plurality of pixels, is configured to emit white light at all the subpixels; a desired color wavelength of the light is extracted through an unillustrated color filter.

A common electrode 44 (e.g. cathode) is on the light-emitting layer 42. The common electrode 44 is on the insulation layer 40 for the bank. The common electrode 44 is continuous over an adjacent pixel electrodes 36. The light-emitting layer 42 is interposed between the pixel electrode 36 and the common electrode 44, for emitting light with its brightness controlled by a current flowing therebetween. At least one unillustrated layer of a hole transport layer and a hole injection layer may be provided between the light-emitting layer 42 and the pixel electrode 36. At least one unillustrated layer of an electron transport layer and an electron injection layer may be provided between the light-emitting layer 42 and the common electrode 44. The pixel electrode 36, the light-emitting layer 42, and the common electrode 44 constitute at least a part of each of a plurality of light-emitting elements 46.

A sealing layer 48 covers the light-emitting elements 46, whereby the light-emitting elements 46 is blocked from moisture. The sealing layer 48 includes an inorganic film such as SiN or SiOx, may be a single layer or may have a laminated structure, which has an organic film such as a resin interposed over and under a pair of inorganic films. The display circuit layer 16 includes at least some layers below the sealing layer 48 laminated on the resin substrate 14, and may include the sealing layer 48.

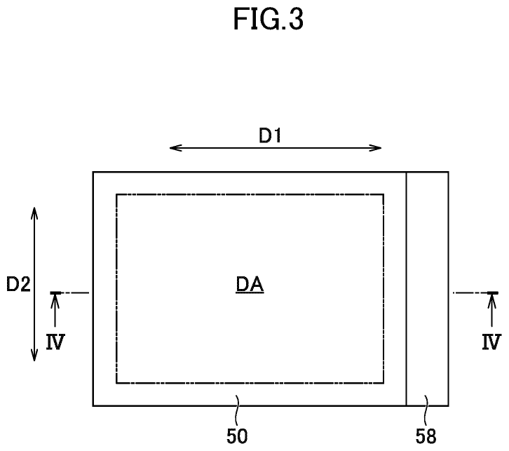

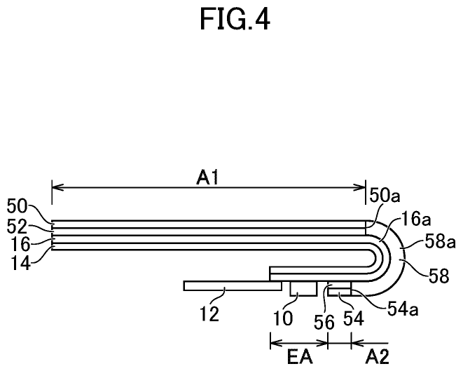

FIG. 3 is a diagram of how to use the display device in FIG. 1. FIG. 4 is a IV-IV line cross-sectional view of the display device in FIG. 3. The display device is foldable to be contained in an unillustrated housing.

The display device has a first film 50. The first film 50 is attached to the display circuit layer 16 in the first area A1, by means of a first adhesive layer 52. The first film 50 and the first adhesive layer 52 overlap with each other, overlap with the display area DA, have light transmission properties for displaying images, and are transparent. The first film 50 is an optically clear film or a polarizing plate. The first area A1 is positioned without curvature, keeping flatness of the display circuit layer 16 with the first film 50 attached thereto. The first film 50 is attached, by means of the first adhesive layer 52, enabling re-attachment in spite of exfoliation.

The display device has a second film 54. The second film 54 is attached to the display circuit layer 16 in the second area A2, by means of a second adhesive layer 56. The second area A2 is apart from the first area A1, to be opposed to the first area A1 when the display device is bent. The second area A2 is positioned without curvature, keeping flatness of the display circuit layer 16, with the second film 54 attached thereto. The second film 54 is attached, by means of the second adhesive layer 56, enabling re-attachment in spite of exfoliation. The display device curves between the first area A1 and the second area A2 of the display circuit layer 16. FIG. 4 illustrates that the second film 54 is not in the electrical connection area EA; the electrical connection area EA and the second film 54 are not opposed to each other.

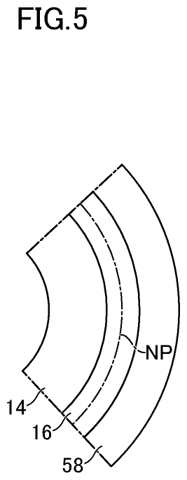

FIG. 5 is an enlarged cross-sectional view of a curvature portion of the display device. The display device has a resin layer 58. The resin layer 58 is cured and in close contact with the display circuit layer 16, without adhesiveness. The resin layer 58 is, as shown in FIG. 4, between the first area A1 and the second area A2 of the display circuit layer 16. Lamination of the resin layer 58 on the display circuit layer 16 enables the display circuit layer 16 to include a neutral plane NP where neither expansion nor contraction is caused by the curvature. This can prevent breaking of an unillustrated trace or cracking of an unillustrated inorganic insulation film. The resin layer 58 may be formed from a material selected among materials, suitable for the curvature or easy to adjust film thickness, leaving much room for material selection.

The resin layer 58, as shown in FIG. 1, is in close contact with respective edge surfaces 50a, 54a of the first film 50 and the second film 54, opposed to each other while the display device is expanded. The resin layer 58 is in contact with both of the edge surface 50a of the first film 50 and the edge surface 54a of the second film 54. The resin layer 58 and the display circuit layer 16 have respective edge surfaces 58a, 16a aligned on both sides in a second direction D2 perpendicular to the first direction D1 (cf. FIG. 4). In other words, the edge surface 58a of the resin layer 58 and the edge surface 16a of the display circuit layer 16 are in direct contact with each other. Or, the resin layer 58 has the edge surface 58a exposed, not opposed to either the first film 50 or the second film 54.

The embodiment can minimize exfoliation because the resin layer 58 is in close contact with the second film 54 on a side apart from the display area DA. Additionally, the second film 54 is attached, by means of the second adhesive layer 56, enabling re-attachment in spite of the exfoliation.

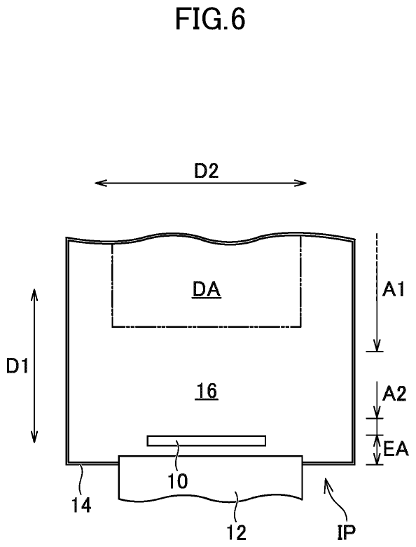

FIGS. 6 to 9 are diagrams of manufacturing method for the display device in the first embodiment.

FIG. 6 illustrates preparation of an intermediate product IP with the resin substrate 14 on which the display circuit layer 16 is laminated. The intermediate product IP is to be cut in a following process, being larger than the product in FIG. 1. The display circuit layer 16 has the first area A1. The display area DA is included in the first area A1. The display circuit layer 16 has the second area A2 apart from the first area A1 in the first direction D1. The integrated circuit chip 10 is bonded to the electrical connection area EA of the display circuit layer 16, to which the flexible printed circuit board 12 is connected.

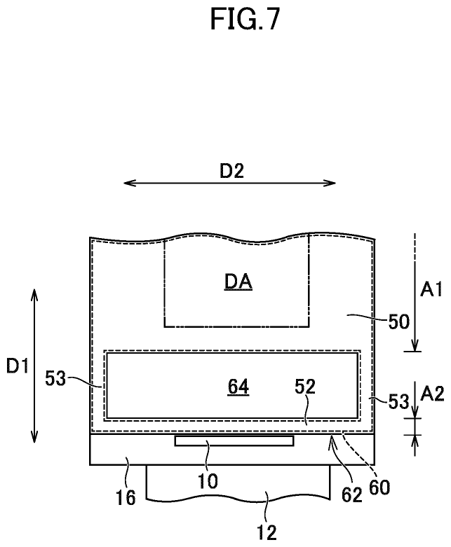

FIG. 7 illustrates that a film 62 is attached to the display circuit layer 16 by means of an adhesive layer 60. The film 62 has an opening 64. The opening 64 is between a pair of portions, in the first direction D1, which have portions corresponding to the first film and the second film 54, in FIG. 1. A pair of connection portions 53, with the opening 64 interposed therebetween in the second direction D2, connect the pair of portions corresponding to the first film 50 and the second film 54 in FIG. 1. The opening 64 is positioned between the first area A1 and the second area A2. The adhesive layer 60 is interposed only between the film 62 and the display circuit layer 16, while not positioned in the opening 64.

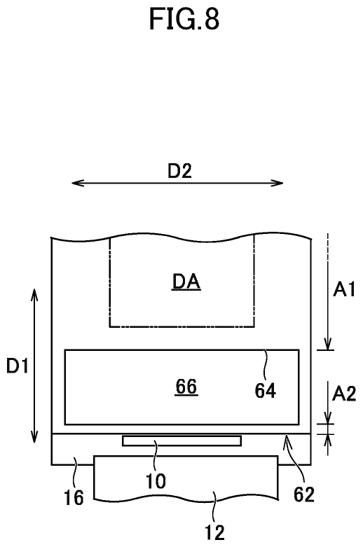

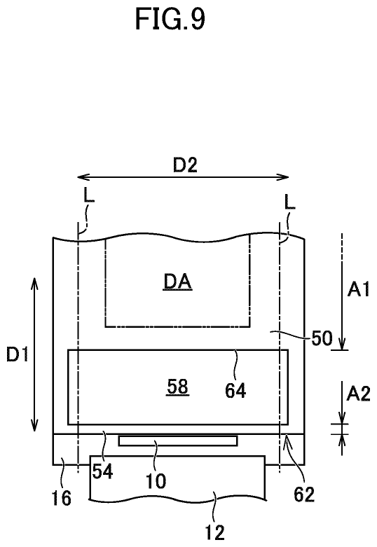

FIG. 8 illustrates that liquid resin 66 is provided in the opening 64 of the film 62 over the display circuit layer 16. The liquid resin 66 is formed selectively from a low viscosity material to be dammed up by the opening 64 of the film 62. This can control thickness of the liquid resin 66 to make it equivalent. As shown in FIG. 5, the display device can be thin or thick enough to position the neutral plane NP in the display circuit layer 16, while bent. The liquid resin 66 is provided all around the edge surface of the opening 64 and in close contact with the film 62. Then, the liquid resin 66 is cured to form the resin layer 58. FIG. 9 illustrates that the product is obtained by cutting the film 62, the display circuit layer 16, and the resin substrate 14 (cf. FIG. 6) under them. A cutting line L is set to pass through the resin layer 58 on its both sides in the second direction D2 perpendicular to the first direction D1. The film 62 has its portions removed, next to the resin layer 58 in the second direction D2, and is separated into the first film 50 and the second film 54. Thus, the resin layer 58 has its cut surfaces exposed on both sides in the second direction D2. By contrast, the resin layer 58 is interposed between the first film 50 and the second film 54, in the first direction D1.

The display device, manufactured in the embodiment, has the resin layer 58 in close contact with the film 62 (second film 54), from a side apart from the display area DA, minimizing exfoliation. The film 62 is attached, by means of the adhesive layer 60 (second adhesive layer 56), whereby re-attachment is possible in spite of the exfoliation.

### Second Embodiment

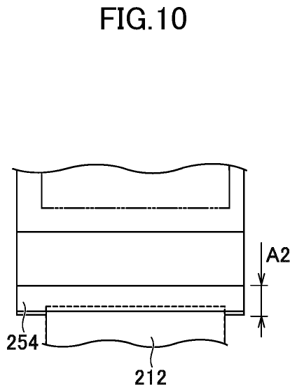

FIG. 10 is a plan view of a display device in a second embodiment. In the embodiment, the flexible printed circuit board 212 is attached to the second area A2 of the second film 254. The second film 254 is attached to and overlaps with a part (edge) of the flexible printed circuit board 212. In this embodiment, the second film 254 can reinforce a bonding portion of the flexible printed circuit board 212.

### Third Embodiment

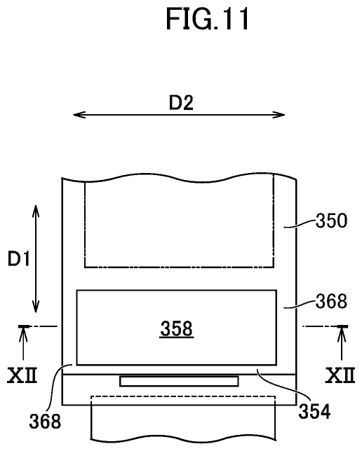

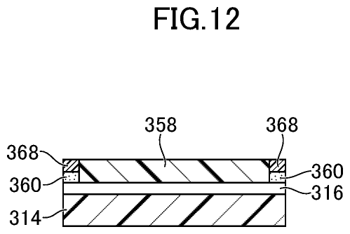

FIG. 11 is a plan view of a display device in a third embodiment. FIG. 12 is a XII-XII line cross-sectional view of the display device in FIG. 11.

The display circuit layer 316 is on the resin substrate 314. The resin layer 358 is provided to stay away from edges of the display circuit layer 316 on its both sides in the second direction D2, i.e. without direct contact with the edges on the both sides. A pair of third films 368 are attached to the display circuit layer 316 on respective edges thereof on the both sides in the second direction D2, by means of respective third adhesive layers 360. The resin layer 358 is in close contact with edge surfaces, of the pair of third film 368, opposed to each other. The third films 368 prevents the resin layer 358 from being exfoliated, on both sides in the second direction D2. The first film 350, the second film 354, and the third films 368 are integrally continuous. What is explained in the first embodiment is applicable hereto.

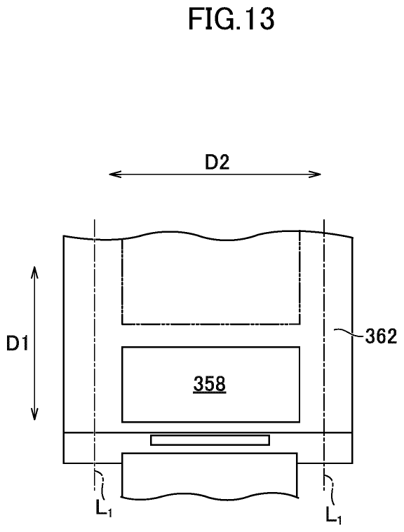

FIG. 13 is a diagram of manufacturing method for the display device in the third embodiment. In this embodiment, the cutting line L1 is set to pass through the film 362, next to both sides of the resin layer 358 in the second direction D2 perpendicular to the first direction D1. The cutting is carried out, leaving the entire resin layer 358 in the product; that is, the resin layer 358 is not cut. Thus, targeted layers to be cut are equivalent, whereby an inorganic film in the display circuit layer 316 is unlikely to crack. Additionally, the film 362 is cut to be left all around and in close contact with the resin layer 358. What is explained in the first embodiment is applicable hereto.

The electronic device is not limited to the organic electroluminescence display device but may be a display device with a light emitting element disposed in each pixel, such as a quantum-dot light emitting diode (QLED), or a liquid crystal display device.

While there have been described what are at present considered to be certain embodiments, it will be understood that various modifications may be made thereto, and it is intended that the appended claims cover all such modifications as fall within the true spirit and scope of the invention.

What is claimed is:

1. A display device comprising:
a resin substrate;
a display circuit layer on the resin substrate, the display circuit layer having a first area including a display area, the display circuit layer having a second area apart from the first area in a first direction;
a first film attached to the first area of the display circuit layer via a first adhesive layer;
a second film attached to the second area of the display circuit layer via a second adhesive layer; and
a resin layer between the first area and the second area of the display circuit layer,
wherein
the resin layer is in contact with an edge surface of the first film opposed to the second film, and the resin layer is in contact with an edge surface of the second film opposed to the first film.

2. The display device according to claim 1, wherein
the resin layer and the display circuit layer have respective edge surfaces in direct contact with each other, on both sides in a second direction perpendicular to the first direction.

3. The display device according to claim 1, wherein
the display circuit layer has a pair of edges on both sides in a second direction perpendicular to the first direction,
the resin layer is in no direct contact with the pair of edges,
the display device further comprises a pair of third films, each of which is attached to a corresponding one of the pair of edges via a third adhesive layer,
the first film, the second film, and the third films are integrally continuous,
the pair of third films have a respective pair of edge surfaces opposed to each other, and
the resin layer is in contact with the pair of edge surfaces.

4. The display device according to claim 1, wherein
the display circuit layer has a third area to an opposite side of the second area from the first area in the first direction, without being opposed to the second film.

5. The display device according to claim 4, further comprising
at least one of a flexible printed circuit board, connected to the third area, and an integrated circuit chip.

6. The display device according to claim 1, further comprising
a flexible printed circuit board connected to the second area of the display circuit layer,
wherein the second film is over the flexible printed circuit board.

7. A method for manufacturing a display device, comprising:
forming a display circuit layer on a resin substrate, the display circuit layer having a first area including a display area, the display circuit layer having a second area apart from the first area in a first direction;
attaching a film to the display circuit layer between the first area and the second area, by means of an adhesive layer, the film having an opening;
providing liquid resin on the display circuit layer and in the opening of the film;
forming a resin layer by curing the liquid resin; and
obtaining a product by cutting the film, the display circuit layer, and the resin substrate, the product including at least a part of the resin layer, the product including a part of the film in close contact with the resin layer and in each of the first area and the second area.

8. The method for manufacturing the display device according to claim 7, wherein
in the process of obtaining the product, a cutting line is set to pass on the film next to both sides of the resin layer in a second direction perpendicular to the first direction.

9. The method for manufacturing the display device according to claim 7, wherein
in the process of obtaining the product, a cutting line is set to pass on the resin layer on both sides in a second direction perpendicular to the first direction.
